(19) United States
(12) Patent Application Publication
(10) Pub. No.: US 2026/0009850 A1
(43) Pub. Date: Jan. 8, 2026

(54) POWER MANAGEMENT CLUSTER DESIGN SYSTEM AND METHOD USING A NO-CODE APPROACH

(71) Applicant: ITDA SEMICONDUCTOR CO., LTD., Hwaseong-si (KR)

(72) Inventors: Ingyu KIM, Hwaseong-si (KR); Hoyeon JEON, Seongnam-si (KR); Ahchan KIM, Hwaseong-si (KR)

(73) Assignee: ITDA SEMICONDUCTOR CO., LTD., Hwaseong-si (KR)

(21) Appl. No.: 19/255,657

(22) Filed: Jun. 30, 2025

(30) Foreign Application Priority Data
Jul. 2, 2024 (KR) 10-2024-0086592
Feb. 26, 2025 (KR) 10-2025-0024982

(51) Int. Cl. G01R 31/3185

(52) U.S. Cl. CPC G01R 31/318583; G01R 31/318575

(57) ABSTRACT

The present disclosure relates to a system and method for designing a power management cluster using a no-code approach, which enables data testing on power elements in a test mode. The system includes at least one processor configured to execute at least one instruction stored in a memory. The instruction includes: generating a power instance including a power management block, a power interface block, and a data controller block based on power component information; generating a data test controller instance including a test mode TDR block and a test control TDR block corresponding to the data controller block; setting a connection between the data controller block and the data test controller instance; and generating hardware code based on hardware code logic and the connection information of the power instance and the data test controller instance.

### STATEMENT REGARDING GOVERNMENT SPONSORED RESEARCH OR DEVELOPMENT

This invention was made with support from the Ministry of SMEs and Startups through a grant funded by the Korea Technology and Information Promotion Agency for SMEs (TIPA), under Project Unique Number 1425182152 and Project Number RS-2023-00302523, within the Startup Growth Technology Development (R&D) program. The project titled “Low-Code Based Low-Power Semiconductor Solution” was executed by ITDA Semiconductor Co., Ltd., with the research period spanning from Jul. 1, 2023, to Jun. 30, 2026. However, no rights in the invention are held by the government of the Republic of Korea.

### CROSS-REFERENCE TO RELATED APPLICATION

This application claims the benefit of and priority to Korean Patent Application Nos. 10-2024-0086592, filed on Jul. 2, 2024, and 10-2025-0024982, filed on Feb. 26, 2025, the entire disclosures of which are incorporated herein by reference in their entirety.

### TECHNICAL FIELD

The present disclosure relates to a system and method for designing a power management cluster of a system-on-chip, and more specifically, to a system and method for designing a power management cluster capable of performing data testing on power elements in a test mode using a no-code approach.

### BACKGROUND

A system-on-chip (SoC) refers to a technology that integrates various functional blocks such as a central processing unit (CPU), a memory, an interface, a digital signal processing circuit, and an analog signal processing circuit into a single semiconductor integrated circuit to implement a computer system or other electronic system, or an integrated circuit (IC) integrated according to the technology. The SoC has evolved into more complex systems including various functional blocks such as processors, multimedia, graphics, interfaces, and security.

The SoC may be driven in a test mode to detect defects during the design and manufacturing process and to verify that the SoC operates properly, and may be driven in a functional mode when passing a test and operating normally.

In general, power and clock design are important for the SoC. The power and clock design process of the SoC may include a power/clock diagram drawing stage, a Verilog coding and scripting stage, a primary documentation stage, a unified power format/standard design constraint (UPF/SDC) file generation stage, an implementation layout design stage, a secondary documentation stage, a design for testability (DFT) controller insertion stage, a hardware system analysis stage, and a software optimization stage.

The power/clock diagram drawing stage visually represents the power and clock structure and draws a block diagram to represent the power domain and clock tree. The power/clock diagram drawing stage merely represents the clock elements and their link relationships in a diagram. The Verilog coding and scripting stage performs the register transfer level (RTL) design of the hardware by writing Verilog code and scripts used to define and implement the functions of the SoC. In other words, developers manually generate RTL code based on the power/clock diagram drawing results.

The primary documentation stage is configured to document the design intent and structure at the beginning of a project and to write various types of documents such as requirements specifications, architecture design, and power/clock diagrams required by a plurality of interested parties such as a verification team and software development team.

The UPF/SDC file generation stage is configured to generate the UPF and SDC files to control power management and timing constraints and to generate inputs required for hardware synthesis.

The implementation layout design stage is configured to design and perform placement of the actual SoC chip layout at the gate level. The secondary documentation stage is configured to update and supplement various documents to reflect changes in the design and implementation. The DFT controller insertion stage is configured to design and integrate the

DFT controller and logic circuits into the SoC for testing and debugging. The hardware system analysis stage is configured to check and analyze the operation of the hardware through simulation and verification, so as to verify the accuracy and efficiency of the design. The software optimization stage is configured to optimize the software performance by profiling and optimizing the software code running on the SoC.

In general, in a power/clock diagram drawing stage, the path of the functional clock/data/reset operating in the functional mode is designed, and in a DFT controller insertion stage, the path of the test clock/reset operating in the test mode is designed. In other words, in the past, the functional clock/reset design stage and the test clock/reset design stage were separated and performed separately. As a result, the clock management unit is designed to provide the functional clock to the IP block through the functional clock path in the functional mode, and to provide the test clock to the IP block through a test clock path different from the functional clock path in the test mode. In addition, the power management unit is designed to provide a functional reset to the IP block through a functional reset path in the functional mode, and to provide a test reset to the IP block through a test reset path different from the functional reset path in the test mode.

A pure test needs to be performed to verify the functionality and detect defects of the digital circuits configuring the SoC. The pure test is a process of verifying the logic paths and states of the digital circuits. In conventional pure tests, when power-up and power-down sequence tests are performed, the power management unit continuously supplies power to the sequence data signal line so that data tests for the IP blocks are performed, while data tests on the elements configuring the power management unit are not performed.

### SUMMARY

An aspect of the present disclosure is directed to providing a system and method for designing a power management cluster using a no-code approach capable of data testing whether a power element that performs a power sequence on an IP block in a test mode operates normally.

An embodiment of the present disclosure may be implemented in various ways, including a device (system), a method, a computer program stored in a computer-readable medium, or a computer-readable medium having a computer program stored therein.

A power management cluster design system using a no-code approach according to an embodiment of the present disclosure is a system for designing a power management cluster using a no-code approach, and includes: a memory configured to store at least one instruction;

a power component storage in which power component information configuring a power management cluster is stored; a hardware code logic storage in which hardware code logic for generating the designed power management cluster as hardware code is stored; and at least one processor configured to execute the at least one instruction stored in the memory. The at least one instruction includes instructions for: generating a power instance including a power management block, a power interface block, and a data controller block based on the power component information; generating a data test controller instance including a test mode TDR block and a test control TDR block corresponding to the data controller block; setting a connection between the data controller block and the data test controller instance; and generating the hardware code based on the hardware code logic and connection information of the power instance and the data test controller instance.

Preferably, the data controller block includes: a first test multiplexer block having a power control signal and preset data connected to input terminals and a pure test mode signal connected to a selection terminal; and a second test multiplexer block having an output terminal of the first test multiplexer block and target test data of the test control TDR block connected to the input terminals and a target test mode signal of the test mode TDR block connected to the selection terminal.

Preferably, the data test controller instance is implemented based on a built-in IEEE1687 standard.

More preferably, the target test mode signal of the test mode TDR block activates or deactivates a test mode, and the target test data of the test control TDR block is transmitted to the second test multiplexer block in the test mode.

More preferably, the test control TDR block is configured with a number of flip-flop blocks corresponding to the number of bits of the target test data.

Preferably, each of the test mode TDR block and the test control TDR block is configured via an internal joint test action group (IJTAG) interface.

More preferably, the power component is at least one of a reset component, an isolation component, a switch control component, a retention component, an automatic power management component, a reference clock gating component, a memory component, a handshake component, a clock link component, a P-channel handshake component, a user-defined output component or a user-defined input component.

A method for designing a power management cluster using a no-code approach according to an embodiment of the present disclosure, the method being performed by at least one processor in a computer system including a power component storage in which power component information configuring a power management cluster is stored and a hardware code logic storage in which hardware code logic for generating the designed power management cluster as hardware code is stored, the method comprising: generating a power instance including a power management block, a power interface block, and a data controller block based on the power component information; generating a data test controller instance including a test mode TDR block and a test control TDR block corresponding to the data controller block; setting a connection between the data controller block and the data test controller instance; and generating hardware code based on the connection information of the power instance and the data test controller instance and the hardware code logic.

Preferably, the data controller block includes: a first test multiplexer block having a power control signal and preset data connected to input terminals and a pure test mode signal connected to a selection terminal; and a second test multiplexer block having an output terminal of the first test multiplexer block and target test data of the test control TDR block connected to the input terminals and a target test mode signal of the test mode TDR block connected to the selection terminal.

Preferably, the data test controller instance is implemented based on a built-in IEEE1687 standard.

More preferably, the target test mode signal of the test mode TDR block activates or deactivates a test mode, and the target test data of the test control TDR block is transmitted to the second test multiplexer block in the test mode.

More preferably, the test control TDR block is configured with a number of flip-flop blocks corresponding to the number of bits of the target test data.

Preferably, each of the test mode TDR block and the test control TDR block is configured via an internal joint test action group (IJTAG) interface.

More preferably, the power component is at least one of a reset component, an isolation component, a switch control component, a retention component, an automatic power management component, a reference clock gating component, a memory component, a handshake component, a clock link component, a P-channel handshake component, a user-defined output component or a user-defined input component.

A computer program stored in a computer-readable medium is provided to execute the aforementioned method according to an embodiment of the present disclosure on a computer.

### Advantageous Effects

An embodiment of the present disclosure provides the following benefits.

According to an embodiment of the present disclosure, when a path of functional data operating in a functional mode is designed in a power/clock diagram drawing stage, a test data path operating in a test mode can be automatically designed at the same time.

According to an embodiment of the present disclosure, since a separate DFT controller insertion stage can be omitted, resources required for designing a power management cluster can be reduced, and the efficiency of design work can be effectively improved.

According to an embodiment of the present disclosure, a power management cluster can be designed using a no-code approach so that an operator can test a data path of a power element in a test mode without coding knowledge or clock process knowledge.

According to an embodiment of the present disclosure, since test data of the same path as a functional data path is generated and a power-up or power-down sequence is performed, data testing for an IP block can be performed accurately.

A power management cluster designed according to an embodiment of the present disclosure can test whether a power element operates normally when a system-on-chip is driven in a test mode, and thus test coverage can be expanded.

The benefits of the present disclosure are not limited to those mentioned above, and other benefits not mentioned herein will be clearly understood by those having ordinary skill in the technical field to which the present disclosure pertains (hereinafter, “those skilled in the art”) from the following description.

### BRIEF DESCRIPTION OF THE DRAWINGS

Embodiments of the present disclosure will be described with reference to the accompanying drawings described below, where similar reference numerals indicate similar elements, but embodiments are not limited thereto, in which:

FIG. 1 is a block diagram illustrating a typical system-on-chip (SoC);

FIG. 2 is a detailed configuration block diagram illustrating a power management cluster included in the SoC of FIG. 1;

FIG. 3 is a detailed configuration diagram illustrating a domain power manager (PMD) and a power management interface (PMIF) of FIG. 2;

FIG. 4 is a partial detailed diagram illustrating a power management cluster designed based on an embodiment of the present disclosure;

FIG. 5 is a configuration diagram illustrating a power management cluster design system using a no-code approach according to an embodiment of the present disclosure;

FIG. 6 is a diagram illustrating an example of a display screen of a power management cluster design system using a no-code approach according to an embodiment of the present disclosure;

FIG. 7 is an operation flow diagram illustrating a power management cluster design method using a no-code approach according to an embodiment of the present disclosure; and

FIG. 8 illustrates an exemplary computing device for performing the method and/or embodiments described above.

### DETAILED DESCRIPTION

Hereinafter, specific details for the practice of the present disclosure will be described in detail with reference to the accompanying drawings. However, in the following description, detailed descriptions of well-known functions or configurations will be omitted when it may make the subject matter of the present disclosure rather unclear.

In the accompanying drawings, the same or corresponding components are assigned the same reference numerals. Further, in the following description of the embodiments, duplicate descriptions of the same or corresponding components may be omitted. However, even if descriptions of components are omitted, it is not intended that such components are not included in any embodiment.

The advantages and features of the embodiments of the present disclosure and methods of achieving the same will be apparent from the embodiments described below in connection with the accompanying drawings. However, the present disclosure is not limited to the embodiments disclosed below, and may be implemented in various different forms, and the present embodiments are merely provided to fully disclose the scope of embodiments to those skilled in the art to which the present disclosure pertains.

The terms used herein will be briefly described prior to describing the disclosed embodiments in detail. The terms used herein have been selected as general terms which are widely used at present in consideration of the functions of the present disclosure, and this may be altered according to the intent of a person skilled in the art, conventional practice, or introduction of new technology. Further, in a specific case, a term is arbitrarily selected by the applicant, and the meaning of the term will be described in detail in a corresponding description of the embodiments. Accordingly, the terms used in the present disclosure should be defined based on the meaning of the terms and the overall content of the present disclosure rather than merely based on the nominal designation of the terms.

As used herein, the singular forms are intended to include the plural forms as well, unless the context clearly indicates the singular forms. Further, the plural forms are intended to include the singular forms as well, unless the context clearly indicates the plural forms. Further, throughout the description, when a portion is stated as including a component, it intends to mean that the portion may additionally include another component, rather than excluding other components, unless specified to the contrary.

In this present disclosure, the terms “comprising,” “having,” or the like are used to specify that features, steps, operations, elements and/or components exist, and they do not preclude the addition of one or more other features, steps, operations, elements, components, and/or combinations thereof.

In the present disclosure, when a particular component is referred to as being “coupled to,” “combined with,” “connected to,” “related to,” or as “responding to” any other component, the particular component may be directly coupled to, combined with, connected to, and/or related to, or may directly respond to the other component; however, the present disclosure is not limited to the relationship. For example, there may be one or more intermediate components between a particular component and another component. In addition, in the present disclosure, “and/or” may include one or more of the listed items or a combination of at least a portion of one or more of the listed items.

In the present disclosure, the terms such as “first” and “second” are used to distinguish a particular component from the other components, and thus the component should not be limited by those terms. For example, a “first” component may be used to indicate a component in a form similar to or the same as a “second” component.

In various embodiments of the present disclosure, the term “power component” may be tools that may be used in designing a power management cluster. The power component may include a reset component, an isolation component, a switch control component, a retention component, an automatic power management component, a reference clock gating component, a memory component, a handshake component, a clock link component, a P-channel handshake component, a user-defined output component, and a user-defined input component.

In various embodiments of the present disclosure, the term “power instance” refers to a power component included in a power management cluster under design and added to a design window by a user's manipulation. The characteristics of the power management cluster may be determined by the power instances included in the power manager component. When the user drags and drops a power component icon from the power component window into the design window area, a power instance corresponding to that power component may be generated. Upon generation of a power instance, a corresponding register may be automatically created. A power instance based on the reset component is referred to as a reset instance, one based on the isolation component is referred to as an isolation instance, one based on the switch control component is referred to as a switch control instance, and one based on the retention component is referred to as a retention instance. Other individual power instances may also be generated based on their respective power components. Once a power instance is created, register field values assigned thereto may also be automatically allocated. Furthermore, hardware code may be generated based on the register field values of the power instance.

A power element, according to the present disclosure, is a hardware-coded module based on a completed power instance and may be configured to constitute a power management cluster. In the present disclosure, the power element may include a power management element, a power interface element, and a data controller.

To sum up, the power component is a material for designing the power management cluster, the power instance is a node included when designing the power management cluster, and the power element is a module that is implemented as hardware code based on the designed power instance and may operate in the power management cluster.

In an embodiment of the present disclosure, the power instance includes a power management block, a power interface block, and a data controller block, and the data controller block may include a first test multiplexer block and a second test multiplexer block. The power management block, the power interface block, and the data controller block are each implemented as hardware codes and may operate as the power management element, the power interface element, and the data controller.

In an embodiment of the present disclosure, a data test controller instance is a node included in the design of the power management cluster, and may include a test mode TDR block and a test control TDR block. The data test controller instance, the test mode TDR block, and the test control TDR block are each implemented as hardware codes and may operate as a data test controller, a test mode TDR, and a test control TDR.

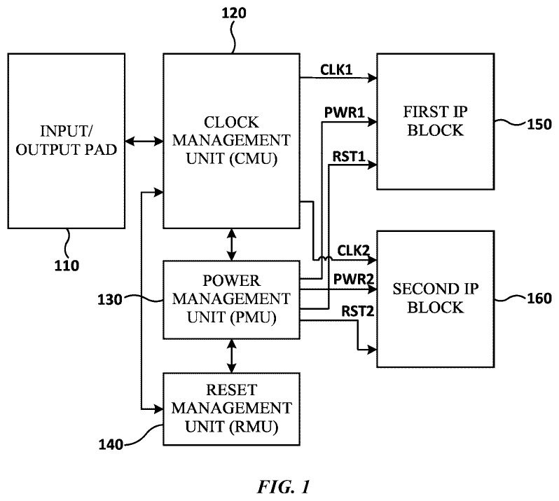

FIG. 1 is a block diagram illustrating a typical system-on-chip (SoC).

The SoC may include an input/output pad 110, a clock management unit (CMU) 120, a power management unit (PMU) 130, a reset management unit (RMU) 140, and one or more intellectual property (IP) blocks 150, 160. When the SoC operates in a functional mode, the CMU 120 may generate first and second functional clocks (CLK1, CLK2) to be provided to each of the first and second IP blocks 150, 160.

Each of the first and second IP blocks 150, 160 is connected to a system bus and may communicate with each other through the system bus. Each of the first and second IP blocks 150, 160 may be a processor, a graphic processor, a memory controller, and an input and output interface block.

The CMU 120 includes a plurality of clock elements, wherein a first functional clock (CLK1) may be provided to the first IP block 150 when the first IP block 150 operates, and a second functional clock (CLK2) may be provided to the second IP block 160 when the second IP block 160 operates.

The PMU 130 includes a plurality of power elements and controls power supplied to the SoC. For example, when the SoC enters a standby mode, the PMU 130 may perform a power-down sequence (PWR1, PWR2) for the first and second IP blocks 150 and 160, so that the power previously supplied to the IP blocks is cut off. In addition, when the SoC operates in a driving mode, the PMU 130 may perform a power-up sequence (PWR1, PWR2) for the first and second IP blocks 150 and 160, so that power is supplied to each IP block.

The RMU 140 detects a reset mode of the SoC and transmits a reset signal (RST1, RST2) to the first and second IP blocks 150, 160 through the PMU 130 so that the hardware may be initialized. In addition, the reset signal generated from the RMU 140 may also be transmitted to the PMU 130 and the CMU 120, so that when the IP block 150, 160 is reset, the power elements of the PMU 130 and the clock elements of the CMU 120 may also be reset.

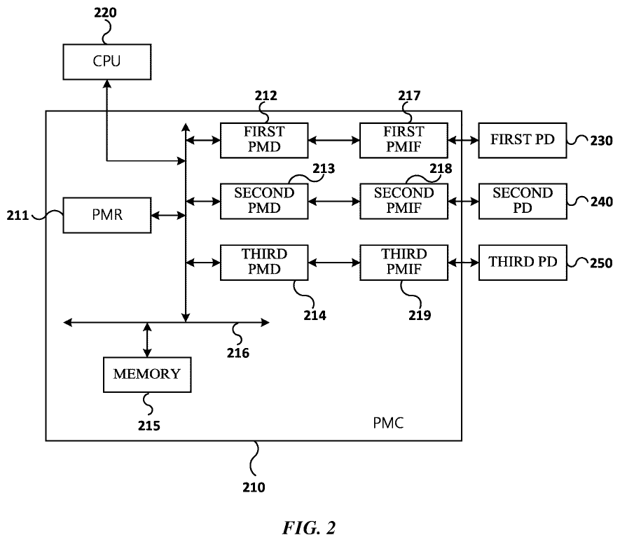

FIG. 2 is a detailed configuration block diagram illustrating a power management cluster included in the SoC of FIG. 1. The SoC contains a fully operational product and system within a single integrated circuit, and may be implemented as a chip, a module, or a system.

The system-on-chip may include a power management cluster (PMC) 210, a central processing unit (CPU) 220 that controls the PMC 210 via software, and at least one power domain (PD) 230, 240, 250. The PDs 230, 240, and 250 may correspond to the IP blocks of FIG. 1. The CPU 220 controls the PMC 210 and may also constitute one of the power domains of the SoC. The PMC 210 may include the power management unit (PMU) 130 of FIG. 1.

The PMC 210 may perform power-up or power-down sequences corresponding to each of the at least one power domains 230, 240, 250. Each of the power domains 230, 240, 250 may perform the power-up or power-down sequence to enter a power-up state or a power-down state. The SoC may include at least one power management cluster 210.

The PD 230, 240, 250 may include a core domain including the CPU 220, a memory domain including a memory subsystem such as a main memory or a cache memory, a graphics and video domain including multimedia elements such as a graphics processing unit or a video encoding/decoding unit, and an input/output domain including input/output interface elements for communication with the outside. Each power domain may include lower sub-power domains.

The power management cluster 210 corresponds to each PD 230, 240, 250 and may include at least one domain power manager (PMD; Power Management for Domain) 212, 213, 214 that controls the power of the corresponding PD 230, 240, 250, a root power manager (PMR; Power Management for Root) 211 that manages the at least one PMD 212, 213, 214, a memory 215 that stores a program that operates the root power manager 211 and the at least one PMD 212, 213, 214, and at least one power management interface (PMIF) 217, 218, 219 disposed between the at least one PMD 212, 213, 214 and the PD 230, 240, 250.

The PMR 211, the PMD 212, 213, 214 and the memory 215 are disposed in an always-on (AON) area, and the power management interfaces 217, 218, 219 are each disposed on the side of the PD 230, 240, 250. The PMD 212, 213, 214 and the power management interfaces 217, 218, 219 correspond one-to-one, and are connected by a P-link.

The at least one PMD 212, 213, 214, the PMR 211 and the memory 215 may be interconnected by an internal bus 216. The program stored in the memory 215 may include instructions and data.

The at least one PMD 212, 213, 214 may perform a power-up or power-down sequence on a corresponding power domain based on a RAM sequence (instructions and data for executing the command) when a domain power-up or power-down command for power control of the power domain is received from the CPU 220. The power control signals of the power-up or power-down sequence are transmitted to the corresponding power domain through the respective power management interfaces 217, 218, 219.

The memory 215 may store, as binary code, instructions and data for the PMR 211 to execute a system power-up or power-down command, and may also store, as binary code, instructions and data for each PMD 212, 213, 214 to execute a domain power-up or power-down command.

In FIG. 2, a system-on-chip including three power domains and three domain power managers is illustrated as an example; however, the number of power domains may be designed differently depending on the complexity of the system-on-chip, and the number of domain power managers may vary according to the number of power domains.

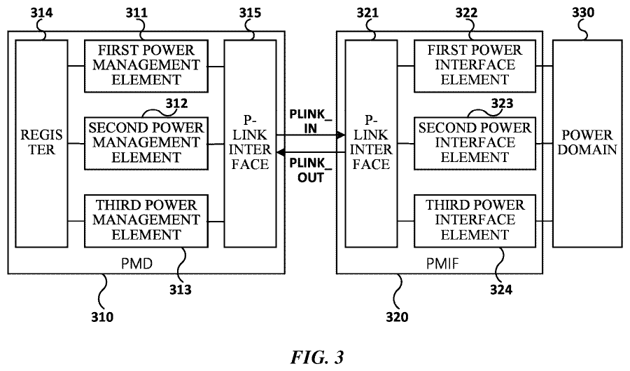

FIG. 3 is a detailed configuration diagram of the domain power manager (PMD) and the power management interface (PMIF) shown in FIG. 2.

The PMD 310 may transmit power control signals to the power domain 330 through the PMIF 320 and perform a power-up or power-down sequence of the power domain 330. Accordingly, the power domain 330 may transition from a power-up state to a power-down state or from a power-down state to a power-up state. The power control signals for performing the power-up or power-down sequence may include a reset signal, an isolation signal, a switch control signal, and a retention signal. In the present disclosure, the term “data” refers to the value of each power control signal. The power control signals may be added, removed, or modified according to the specifications of the power domain 330 and may be generated in correspondence with respective power management elements 311, 312, and 313 of the PMD 310.

The PMD 310 may include a plurality of power management elements 311, 312, and 313 for transmitting and receiving power control signals with the power domain 330, a register 314 for controlling each of the power management elements 311, 312, and 313, and a P-link interface 315 for interfacing the plurality of power management elements 311, 312, and 313 with the PMIF 320.

The PMIF 320 serves to physically connect the PMD 310 and the power domain 330. The PMIF 320 may include a P-link interface 321 for interfacing with the PMD 310, and a plurality of power interface elements 322, 323, and 324 that correspond one-to-one to the power management elements 311, 312, and 313 and interface between the power management elements and the power domain 330.

In FIG. 3, the PMD 310 is exemplified as including three power management elements 311, 312, and 313, and the PMIF 320 is exemplified as including three power interface elements 322, 323, and 324, but the number of power management elements and power interface elements may be designed to be a different number depending on the function of the PMD.

The power management element of the PMD 310 and the power interface element of the PMIF 320 may correspond to each other to configure one power element. The power element may include at least one of a reset element for transmitting a reset signal to the power domain, an isolation element for transmitting an isolation signal to the power domain, a switch control element for transmitting a switch control signal to the power domain, a retention element for transmitting a retention signal to the power domain, an automatic power manager element for automatically performing power-up or power-down by a hardware trigger signal, a reference clock gating element for gating a reference clock supplied to the power domain, a handshake element for generating a handshake control signal with the power domain, a clock link element for generating a link control signal with the clock management unit, a P-channel handshake element for generating a P-channel handshake control signal with the power domain, a user-defined output element for generating a user-defined output signal within the power domain, and a user-defined input element for generating a user-defined input signal within the power domain.

Accordingly, the power management elements 311, 312, 313 may include a reset management element, an isolation management element, a switch control management element, a retention management element, an automatic power management element, a reference clock gating management element, a handshake management element, a P-channel handshake management element, a user-defined output management element, and a user-defined input management element.

The power interface elements 322, 323, 324 may include a reset interface element corresponding to the reset management element, an isolation interface element corresponding to the isolation management element, a switch control interface element corresponding to the switch control management element, a retention interface element corresponding to the retention management element, an automatic power interface element corresponding to the automatic power management element, a reference clock gating interface element corresponding to the reference clock gating management element, a handshake interface element corresponding to the handshake management element, a P-channel handshake interface element corresponding to the P-channel handshake management element, a user-defined output interface element corresponding to the user-defined output management element, and a user-defined input interface element corresponding to the user-defined input management element.

The PMD 310 and the PMIF 320 communicate via a P-link interface 315 and 321, and signals transmitted from the PMD 310 to the PMIF 320 are transmitted through a P-link input (PLINK_IN) line. Signals transmitted from the PMIF 320 to the PMD 310 are transmitted through a P-link output (PLINK_OUT) line.

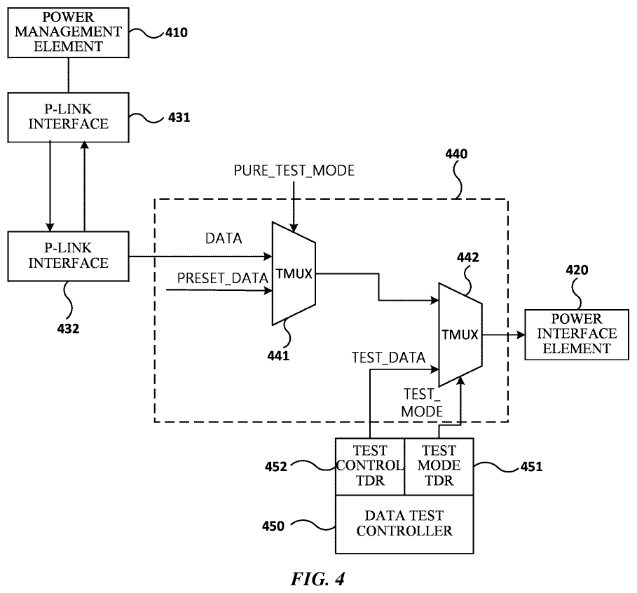

FIG. 4 is a partial detailed diagram illustrating a power management cluster (PMC) designed based on an embodiment of the present disclosure. A power element is divided into a power management element 410 and a power interface element 420, where the power management element 410 may be disposed on the side of the PMD, and the power interface element 420 may be disposed on the side of the power domain. The power management element 410 may correspond to any one of the first to third power management elements 311 to 313 of FIG. 3, and the power interface element 420 may correspond to any one of the first to third power interface elements 322 to 324 of FIG. 3. The power management element 410 and the power interface element 420 may communicate with each other through a P-link interface 431, 432.

The power element includes a data controller 440 disposed upstream of the power interface element 420. When the system-on-chip is operated in a functional mode, the data controller 440 transmits a power control signal output from the power management element 410 to the power interface element 420, and when the system-on-chip is operated in a test mode, the data controller 440 transmits a test signal for testing the power domain and the power interface element 420 to the power interface element 420 under the control of a data test controller 450.

The data test controller 450 provides the data controller 440 with a target test mode signal (TEST_MODE) that indicates whether the power interface element 420 is in a test mode, and target test data (TEST_DATA). The target test data (TEST_DATA) is provided to the power interface element 420 while the target test mode is activated.

The data controller 440 receives a pure test mode signal (PURE_TEST_MODE) indicating whether the target is in a pure test mode, a target test mode signal (TEST_MODE), and target test data (TEST_DATA). When the pure test mode is activated, the data controller 440 transmits preset data (PRESET_DATA) to the power interface element 420, and when both the pure test mode and the target test mode are activated, it transmits the target test data (TEST_DATA) to the power interface element 420.

When the pure test mode is deactivated, the data controller 440 transmits a power control signal (DATA) provided from the power management element 410 to the power interface element 420.

The power interface element 420 may be a power interface element related to a power-up or power-down sequence of the power domain. The power interface element 420 may include an isolation interface element, a switch control interface element, a retention interface element, an automatic power management interface element, and a reference clock gating interface element.

The pure test mode signal is the most global test mode signal that indicates that the system-on-chip is in a test mode. The system-on-chip may perform various test modes such as a scan test, a built-in self-test (BIST), and a hard macro test, and the pure test mode signal becomes ‘high’ in all of these test modes.

In order to test the power domain in the pure test mode, active low data or active high data may need to be provided depending on the power interface element 420. For example, when the power interface element 420 is the automatic power management interface element, active low data may need to be provided, and when the power interface element 420 is the reference clock gating interface component, active high data may need to be provided. In the pure test mode, data to be provided to the power interface element 420 may be set as the preset data (PRESET_DATA). The provision of the preset data to the power interface element 420 in the pure test mode is necessary to make the power control signal a specific value before selecting a test mode regardless of the type of test mode.

The data controller 440 may include: a first test multiplexer 441 which receives a power control signal (DATA) and preset data (PRESET_DATA) as input terminals and a pure test mode signal (PURE_TEST_MODE) as a selection terminal and selects and outputs between the power control signal (DATA) and preset data (PRESET_DATA) depending on whether the pure test mode is activated; and a second test multiplexer 442 which receives an output of the first test multiplexer 441 and target power test data (TEST_ DATA) as input terminals and the target power test mode signal (TEST_MODE) as a selection terminal and selects and outputs between the output of the first test multiplexer 441 and the target test data (TEST_DATA) depending on whether the target test mode is activated.

The data test controller 450 may include a test mode test data register (TDR) 451 that outputs the target power test mode signal (TEST_MODE) indicating whether a target test mode of the power interface element 420 is activated or deactivated, and a test control TDR 452 that outputs the target test data (TEST_DATA) when the power interface element 420 is activated in the test mode.

The data test controller 450 may be a controller based on a built-in IEEE1687 standard. The data test controller 450 may set the test mode TDR 451 and the test control TDR 452 through an internal joint test action group (IJTAG) interface. The test mode TDR 451 and the test control TDR 452 may each be implemented with a flip-flop-based shift register structure.

The test mode TDR 451 may be configured with a flip-flop and may output the target test mode signal (TEST_MODE) indicating data test mode activation/deactivation of the power interface element 420 to the data controller 440. In other words, the target test mode signal may be a 1-bit signal indicating data test mode activation/deactivation.

The test control TDR 452 may be configured with a flip-flop and may output the target test data (TEST_DATA) to the data controller 440. The target test data (TEST_ DATA) may be a value that determines whether to output active data or non-active data to the power interface element 420 when the data test mode is activated. Accordingly, the target test data (TEST DATA) may be a 1-bit signal.

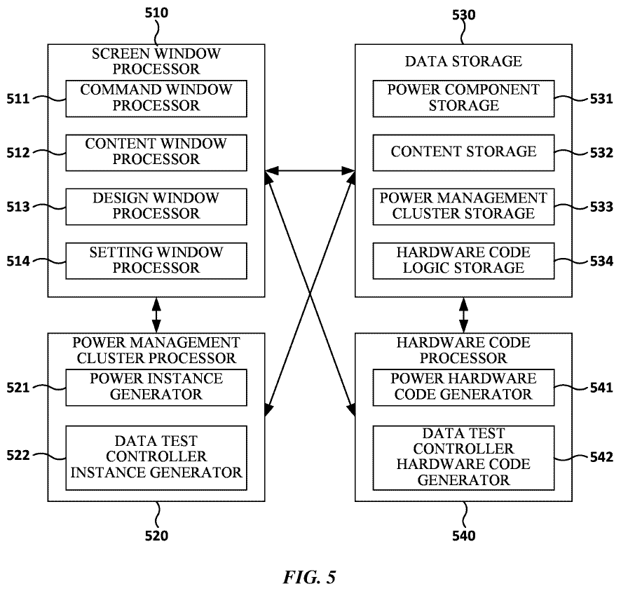

FIG. 5 is a configuration diagram illustrating a power management cluster design system using a no-code approach according to an embodiment of the present disclosure. The power management cluster design system using the no-code approach according to an embodiment of the present disclosure may be implemented as a computer system. The power management cluster design system of an embodiment of the present disclosure may be a system for designing the power management cluster of FIG. 4.

The power management cluster design system using the no-code approach according to an embodiment of the present disclosure may include: a screen window processor 510 that detects a user input and outputs a processing result of the user input on a display screen; a power management cluster processor 520 that designs a power management cluster by generating at least one power instance based on power component information, generating a data test controller instance, and setting a connection between the power instance and the data test controller instance; a data storage 530 that stores hardware code logic for generating hardware code based on the power component information and the designed power management cluster;

and a hardware code processor 540 that generates hardware code corresponding to the designed power management cluster using the hardware code logic.

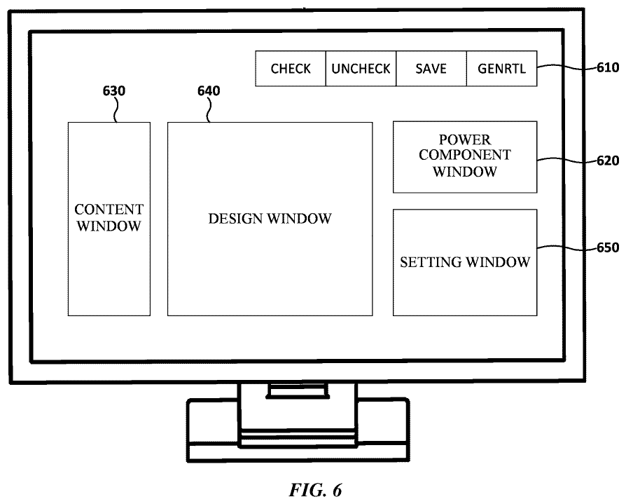

FIG. 6 is a diagram illustrating an example of a display screen of a power management cluster design system using a no-code approach according to an embodiment of the present disclosure.

The display screen of the power management cluster design system using the no-code approach according to an embodiment of the present disclosure may include: a command window 610 in which a user command is input; a power component window 620 in which power component icons are displayed; a content window 630 in which an environment for adding, deleting, and changing a list of power management clusters under design is provided and a list of power instances configuring each power management cluster under design and functional information of each power instance are hierarchically displayed; a design window 640 in which a power diagram of the power management cluster under design is displayed and an environment for adding, deleting, and changing a power instance configuring the power management cluster under design are provided; and a setting window 650 in which a functional setting environment for the power instance selected in the design window 640 is provided.

The command window 610 may include a check button for receiving a check command for errors in the power diagram of the power management cluster under design and the setting values of power instances that configure the power management cluster under design, an uncheck button for receiving a command to deactivate the check result, a save button for receiving a save command for the power diagram displayed in the design window 640, and a GENRTL button for receiving a hardware code generation command for the power diagram displayed in the design window 640.

The power component window 620 may display icons of a power component list that may be utilized in the design of the power management cluster. The power components may include a reset component, an isolation component, a switch control component, a retention component, an automatic power management component, a reference clock gating component, a memory component, a handshake component, a clock link component, a P-channel handshake component, a user-defined output component, and a user-defined input component.

Each power component internally includes a power management block, a power interface block, and a data controller block. The power management block is a design block implemented in hardware code and operates as the power management element of FIG. 4, the power interface block is a design block implemented in hardware code and operates as the power interface element of FIG. 4, and the data controller block is a design block implemented in hardware code and operates as the data controller of FIG. 4.

The content window 630 displays a list of power management clusters under design and provides an environment for adding, deleting, and changing power management clusters under design. The list of power instances that configure the corresponding power management clusters under design may be displayed down the list of each power management cluster under design. The design window 640 displays a power diagram of the power management cluster under design and provides an environment for adding, deleting, and changing power instances that configure the power management clusters under design. When a user moves any power component of the power component window 620 to the design window 640 by dragging and dropping, the power instance corresponding to the corresponding power component may be generated in the corresponding power management cluster under design.

The setting window 650 provides a functional setting environment for the power instance selected in the design window 640.

### Screen Window Processor 510

The screen window processor 510 may include: a command window processor 511 that displays buttons for receiving user commands on the command window 610 and detects input of each button of the command window 610 to cause an operation corresponding to the input button to be performed; a content window processor 512 that hierarchically displays a list of power management clusters under design and the list of power instances and register information included in each power management cluster under design on the content window 630 and detects user input on the content window 630 to cause an operation corresponding to the user input to be performed; a design window processor 513 that causes a power diagram of the power management cluster under design selected by a user to be displayed on the design window 640 and detects the user input on the design window 640 to cause an operation corresponding to the user input to be performed; and a setting window processor 514 that displays setting information of the power management cluster and power instance under design selected by a user in the setting window 650 and detects user input in the setting window 650 to perform an operation corresponding to the user input.

The command window processor 511 checks for errors in the power diagram of the power management cluster under design and the setting values of the power instances configuring the power management cluster under design when the check button is selected, and displays the portion where the error occurred. When the uncheck button is selected, the command window processor 511 restores the error portion displayed in the power diagram of the power management cluster under design to its original state and displays the same. When the save button is selected, the command window processor 511 saves the work content of the power management cluster under design displayed in the design window 640 in the data storage 530. When the GENRTL button is selected, the command window processor 511 generates hardware code for the power diagram of the power management cluster under design displayed in the design window 640.

The content window processor 512 provides an environment for adding, deleting, and changing a list of power management clusters under design and the list of power instances included in each power management cluster under design. The content window processor 512 may hierarchically display the list of power instances and the register information of each power instance down each power management cluster under design. A user may add, delete, and change the name of the power management cluster under design in the content window 630, and the list of power management clusters under design may be added, deleted, and changed in a power management cluster storage 533 in response to a user input. When a user changes the name of the power management cluster under design, the content window processor 512 may change not only the name of the power management cluster under design but also the name and register name of the power instance down the power management cluster under design all at once.

The design window processor 513 displays the power diagram of the power management cluster under design in the design window 640 and provides an environment for adding, deleting, and changing the power instance that configures the power management cluster under design. When a user performs an operation to add an arbitrary power component of the power component window 620 to the design window 640, the design window processor 513 detects the same and causes a power instance addition operation to be performed.

The setting window processor 514 causes the setting information of the power instance and power management cluster under design to be displayed and detects a user input in the setting window 650 to cause an operation corresponding to the user input to be performed.

### Data Storage 530

The data storage 530 may include: a power component storage 531 that stores power component information; a content storage 532 that stores a list of power instances included in a power management cluster under design and a list of registers corresponding to the power instances; a power management cluster storage 533 that stores functional information of individual power instances included in the power management cluster under design and information on data test controller instances included in the power management cluster under design; and a hardware code logic storage 534 that stores hardware code logic for generating hardware code based on the power management cluster information under design. The data test controller instance is a design element implemented as hardware code to operate as the data test controller of FIG. 4.

The power components stored in the power component storage 531 may include a reset component, an isolation component, a switch control component, a retention component, an automatic power manager component, a reference clock gating component, a memory component, a handshake component, a clock link component, a P-channel handshake component, a user-defined output component, and a user-defined input component. Each power component internally includes a power management block, a power interface block, and a data controller block.

The content storage 532 stores a power management cluster under design, a list of power instances, and a list of registers corresponding to the power instances.

The power management cluster storage 533 stores information on each power instance included in the power management cluster under design, information on a data test controller instance included in the power management cluster under design, and connection information between the power instance and the data test controller instance.

The hardware code logic storage 534 stores hardware code logic for generating hardware code based on the information on a designed power management cluster, power instance information, and register information. When a power instance is generated as hardware code, it may be realized as a power element, and accordingly, a power management block, a power interface block, and a data controller block of each power instance may be implemented as a power management element, a power interface element, and a data controller of FIG. 4, respectively. In addition, each data test controller instance may be implemented as a data test controller of FIG. 4, and the data controller may be connected to the data test controller.

### Power Management Cluster Processor 520

The power management cluster processor 520 may include: a power instance generator 521 configured to generate a new power instance including a power management block, a power interface block, and a data controller block based on power component information; and a data test controller instance generator 522 configured to generate a data test controller instance connected to the data controller block. The data test controller instance may be configured to output test data control signals to the data controller block in a test mode.

The power instance generator 521 may be triggered to generate a new power instance when a user adds any power component from the power component window 620 to the design window 640. The name of the new power instance may include the name of the power management cluster under design that includes the new power instance and the type information of the power component of the new power instance. The power instance may internally include a power management block, a power interface block, and a data controller block.

The data controller block includes: a first test multiplexer block in which a power control signal and preset data are connected to input terminals, and a pure test mode signal is connected to a selection terminal; and a second test multiplexer block in which an output terminal of the first test multiplexer block and target test data are connected to input terminals, and a target test mode signal is connected to a selection terminal. The data controller block may be converted into hardware code and implemented as the data controller of FIG. 4.

The data test controller instance generator 522 may automatically operate to generate a data test controller instance and connection information between the power instance and the data test controller instance, when a power instance is generated even without a user input. The data test controller instance may include a test mode TDR block and a test control TDR block. The test mode TDR block is configured to provide a target test mode signal to a second test multiplexer block, and the test control TDR block is configured to provide target test data to the second test multiplexer block. The data test controller instance generator 522 may generate the test control TDR block configured as a flip-flop chain corresponding to the number of bits of the target test data.

The data test controller instance is a controller based on the built-in IEEE 1687 standard, and the test mode TDR block and the test control TDR block may each be configured via the IJTAG (Internal Joint Test Action Group) interface.

### Hardware Code Processor 540

The hardware code processor 540 may include: a power hardware code generator 541 that generates hardware code corresponding to a functional module of a power element based on the designed power instance information; and a data test controller hardware code generator 542 that generates hardware code corresponding to a data test controller based on the data test controller instance information. By driving the hardware code processor 540, the power instance and the data test controller instance may be implemented as the power element and the data test controller of FIG. 4, respectively.

The hardware code processor 540 may be executed so that an operation corresponding to the selected GENRTL button of the command window 610 is performed. A user may select and execute the GENRTL button while the power diagram of the power management cluster under design is displayed in the design window 640, and may also execute the check button before executing the GENRTL button to verify in advance whether there is an error in the power diagram.

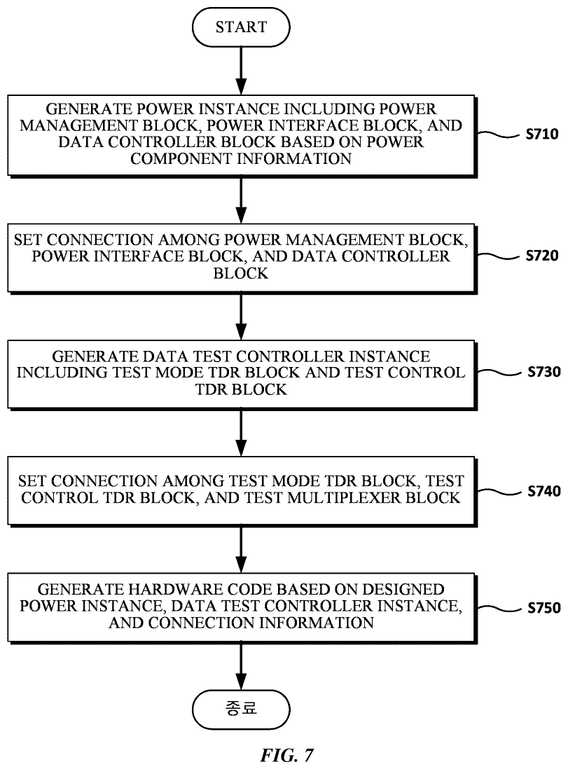

FIG. 7 is an operation flow diagram illustrating a power management cluster design method using a no-code approach according to an embodiment of the present disclosure. The power management cluster design method using the no-code approach according to an embodiment of the present disclosure may be executed by a processor of a computer system.

The computer system includes: a power component storage storing power component information including a power management block, a power interface block and a data controller block; and a hardware code logic storage storing hardware code logic for generating the designed power management cluster as hardware code.

The processor generates a new power instance including the power management block, the power interface block, and the data controller block based on the power component information (S710). The data controller block includes a first test multiplexer block having a power control signal and preset data connected to input terminals and a pure test mode signal connected to a selection terminal, and a second test multiplexer block having an output terminal of the first test multiplexer block and target test data connected to input terminals and the target test mode signal connected to a selection terminal.

The processor sets a connection among the power management block, the power interface block, and the data controller block (S720). In other words, P-link connection information is set between the power management block and the data controller block, and connection information is set between the data controller block and the power interface block.

The processor generates a data test controller instance for generating test control signals in a test mode (S730). The data test controller instance includes the test mode TDR block and the test control TDR block. The test mode TDR block is set to output the target test mode signal to the data controller block, and the test control TDR block is set to output the target test data to the data controller block. The test control TDR block may be configured of as many flip-flop blocks as the number of bits of target test data.

The processor sets a connection among the test mode TDR block, the test control TDR block, and the data controller block (S740). In other words, the target test mode signal of the test mode TDR block is connected to the selection terminal of the second test multiplexer block, and the target test data of the test control TDR block is connected to the input terminal of the second test multiplexer block.

The processor generates hardware code for the power management cluster, which is designed based on the power instance, the data test controller instance, their connection setting information, and the hardware code logic (S750).

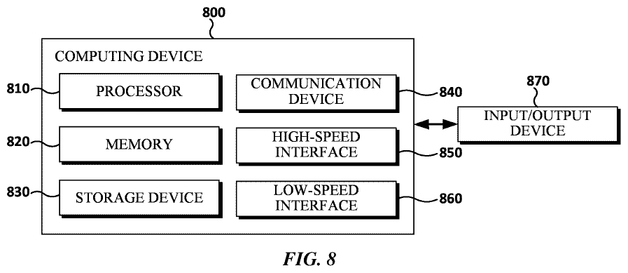

FIG. 8 illustrates an exemplary computing device 800 for performing the above-described methods and/or embodiments, among others. According to an embodiment, the computing device 800 may be implemented using hardware and/or software configured to interact with a user. The computing device 800 may include, but is not limited to, a laptop computer, a desktop computer, a workstation, a personal digital assistant, a server, a blade server, and a mainframe computer. The components, their connections, and their functions of the computing device 800 are provided for illustrative purposes only and are not intended to limit the implementations of the present disclosure described and/or claimed herein.

The computing device 800 includes a processor 810, a memory 820, a storage device 830, a communication device 840, a high-speed interface 850 connected to the memory 820 and to a high-speed expansion port, and a low-speed interface 860 connected to a low-speed bus and a storage device. Each of the components 810, 820, 830, 840, 850, and 860 may be interconnected using various buses, and may be mounted on the same main board or mounted and connected in other suitable manners. The processor 810 may be configured to process computer program instructions by performing basic arithmetic, logic, and input/output operations. For example, the processor 810 may process instructions stored in the memory 820 and the storage device 830 and/or instructions executed within the computing device 800, and may display graphic information on an external input/output device 870, such as a display device connected to the high-speed interface 850.

The communication device 840 may provide a configuration or function that enables communication between the input/output device 870 and the computing device 800 through a network, and may also support communication between the input/output device 870 and/or the computing device 800 and another external device. For example, a request or data generated by a processor of the external device according to an arbitrary program code may be transmitted to the computing device 800 over a network under the control of the communication device 840. Conversely, a control signal or command issued under the control of the processor 810 of the computing device 800 may be transmitted to another external device via the communication device 840 and the network.

FIG. 8 illustrates that the computing device 800 includes one processor 810 and one memory 820, but is not limited thereto. The computing device 800 may be implemented using a plurality of memories, a plurality of processors, and/or a plurality of buses. In addition, although FIG. 8 illustrates the presence of a single computing device 800, the present disclosure is not limited thereto, and a plurality of computing devices may interact with each other to perform operations required to execute the method described above.

The memory 820 may store information in the computing device 800. According to an embodiment, the memory 820 may include a volatile memory unit or a plurality of memory units. Additionally or alternatively, the memory 820 may be composed of a non-volatile memory unit or a plurality of memory units. In addition, the memory 820 may be implemented using a different type of computer-readable medium, such as a magnetic disc or an optical disc. In addition, an operating system and at least one program code and/or instruction may be stored in the memory 820.

The storage device 830 may be one or more mass storage devices for storing data for the computing device 800. For example, the storage device 830 may be configured to include a hard disc; a magnetic disc such as a portable disc; an optical disc; a semiconductor memory device such as an erasable programmable read-only memory (EPROM), an electrically erasable PROM (EEPROM), and a flash memory; and a computer-readable medium including a CD-ROM or DVD-ROM disc; or the storage device 830 may be configured to include the computer-readable medium. In addition, the computer program may be implemented tangibly in the computer-readable medium.

The high-speed interface 850 and the low-speed interface 860 may be used for interaction with the input/output device 870. For example, an input device may include a camera including an audio sensor and/or an image sensor, a keyboard, a microphone, and a mouse; an output device may include a display, a speaker, and a haptic feedback device. In another example, the high-speed interface 850 and the low-speed interface 860 may be used for interfacing with a device in which a configuration or function for performing input and output operations is integrated into one entity, such as a touch screen.

According to an embodiment, the high-speed interface 850 manages bandwidth-intensive operations for the computing device 800, while the low-speed interface 860 manages less bandwidth-intensive operations than the high-speed interface 850, where the above functional assignment has been made merely for an illustrative purpose. According to an embodiment, the high-speed interface 850 may be coupled to high-speed expansion ports capable of accommodating the memory 820, the input/output device 870, and various expansion cards (not shown). In addition, the low-speed interface 860 may be coupled to the storage device 830 and low-speed expansion ports. In addition, the low-speed expansion port, which may include various communication ports (for example, USB, Bluetooth, Ethernet, and wireless Ethernet), may be coupled to one or more input/output devices 870, such as a keyboard, a pointing device, and a scanner, or a networking device, such as a router or a switch, through a network adaptor.

The computing device 800 may be implemented in many different forms. For example, the computing device 800 may be implemented as a standard server or a group of standard servers. Additionally or alternatively, the computing device 800 may be implemented as part of a rack server system or may be implemented as a personal computer, such as a laptop computer. In this connection, components from the computing device 800 may be combined with other components of an arbitrary mobile device (not shown). The computing device 800 may include one or more other computing devices or may be configured to communicate with one or more computing devices.

FIG. 8 illustrates that the input/output device 870 is not included in the computing device 800, but is not limited thereto, and the input/output device 870 may be configured to be integrated into the computing device 800 to form a single device. In addition, FIG. 8 illustrates that the high-speed interface 850 and/or the low-speed interface 860 are illustrated as being configured separately from the processor 810, but is not limited thereto, and the high-speed interface 850 and/or the low-speed interface 860 may be configured to be included in the processor 810.

The method and/or various embodiments described above may be implemented in digital electronic circuitry, computer hardware, firmware, software, and/or a combination thereof. Various embodiments of the present disclosure may be executed by a data processing device, for example, one or more programmable processors and/or one or more computing devices; or implemented as a computer-readable medium and/or a computer program stored on a computer-readable medium. The computer program may be written in any form of programming language including a compiled language or an interpreted language and may be distributed in any form such as a stand-alone program, a module, or a subroutine. The computer program may be distributed via a plurality of computing devices connected through one computing device and the same network and/or a plurality of distributed computing devices connected through a plurality of different networks.

The method and/or various embodiments described above may be performed by one or more processors configured to execute one or more computer programs that process, store, and/or manage arbitrary functions by operating based on input data or generating output data. For example, the method and/or various embodiments of the present disclosure may be performed by a special-purpose logic circuit such as a Field Programmable Gate Array (FPGA) or an Application Specific Integrated Circuit (ASIC); an apparatus and/or a system for performing the method and/or various embodiments of the present disclosure may be implemented as a special-purpose logic circuit such as an FPGA or an ASIC.

The one or more processors executing the computer program may include a general-purpose or special-purpose microprocessor and/or one or more processors of an arbitrary type of digital computing device. The processor may receive instructions and/or data from each of the read-only memory and the random-access memory or may receive instructions and/or data from the read-only memory and the random-access memory. In an embodiment of the present disclosure, the components of a computing device performing the method and/or embodiments may include one or more processors for executing instructions; and one or more memories for storing instructions and/or data.

According to an embodiment, the computing device may send and receive data to and from one or more mass storage devices for storing data. For example, the computing device may receive data from a magnetic or optical disc and transmit data to the magnetic or optical disc. A computer-readable medium suitable for storing instructions and/or data related to a computer program may include any form of non-volatile memory including a semiconductor memory device such as an Erasable Programmable Read-Only Memory (EPROM), an Electrically Erasable PROM (EEPROM), and a flash memory device, without being limited thereto. For example, a computer-readable medium may include a magnetic disc such as an internal hard disc or a removable disc, a photomagnetic disk, a CD-ROM disc, and a DVD-ROM disc.

To provide interaction with a user, the computing device may include a display device (for example, a cathode ray tube (CRT) or a liquid crystal display (LCD)) for providing or displaying information to a user and a pointing device (for example, a keyboard, a mouse, or a trackball) through which the user may provide input and/or commands to the computing device by the user, without being limited thereto. In other words, the computing device may further include any other kind of device for providing interaction with the user. For example, the computing device may provide any form of sensory feedback to the user for interaction with the user, including visual feedback, auditory feedback, and/or tactile feedback. In response to the feedback, the user may provide input to the computing device through various gestures including a visual expression, voice, and motion.

In the present disclosure, various embodiments may be implemented in a computing device that includes a back-end component (for example, a data server), a middleware component (for example, an application server), and/or a front-end component. In this connection, the components may be interconnected by any form or any medium of digital data communication, such as a communication network. According to an embodiment, the communication network includes a wired network such as Ethernet, a wired home network (Power Line Communication), a telephone line communication device, and RS-serial communication; a wireless network such as a mobile communication network, a wireless LAN (WLAN), Wi-Fi, and Bluetooth; or a combination of the wired and wireless networks. For example, the communication network may include a local area network (LAN) and a wide area network (WAN).

A computing device based on the illustrative embodiments described herein may be implemented using hardware and/or software configured to interact with a user, including a user device, a user interface (UI) device, a user terminal, or a client device. For example, the computing device may include a portable computing device such as a laptop computer. Additionally or alternatively, the computing device may include a Personal Digital Assistants (PDA), a tablet PC, a game console, a wearable device, an Internet of Things (IoT) device, a virtual reality (VR) device, and an augmented reality (AR) device, but is not limited thereto. The computing device may further include other types of devices configured to interact with a user. In addition, the computing device may include a portable communication device (e.g., a mobile phone, a smartphone, or a wireless cellular phone) suitable for wireless communication over a network, such as a mobile communication network. The computing device may be configured to communicate wirelessly with a network server using wireless communication technologies and/or protocols such as Radio Frequency (RF), Microwave Frequency (MWF), and/or Infrared Ray Frequency (IRF).

Various embodiments of the present disclosure, including specific structural and functional details, are illustrative in nature. Accordingly, the embodiments of the present disclosure are not limited to those described above and may be implemented in various other forms. In addition, the terms used in the present disclosure are intended for describing some embodiments and should not be construed as limiting the embodiments. For example, singular words and the descriptions above may be construed to include plural forms unless the context dictates otherwise.

Unless defined otherwise, terms used in the present disclosure, including technical or scientific terms, may convey the same meaning understood generally by those skilled in the art to which the present disclosure belongs. Among the terms used in the present disclosure, commonly used terms, such as those defined in ordinary dictionaries, should be interpreted to convey the same meaning in the context of related technology.

The present disclosure has been described with reference to particular embodiments; however, various modifications and changes may be made without departing from the technical scope of the present disclosure that may be understood by those skilled in the art to which the present disclosure belongs. In addition, it should be understood that the modifications and changes fall within the technical scope of the appended claims.

[Detailed Description of Main Elements]

| | |
|---|---|
| 510: screen window processor | 511: command window processor |
| 512: content window processor | 513: design window processor |
| 514: setting window processor | 520: power management cluster |
| | processor |
| 521: power instance generator | 522: data test controller instance |
| | generator |
| 530: data storage | 531: power component storage |
| 532: content storage | 533: power management cluster storage |
| 534: hardware code logic storage | |
| 540: hardware code processor | 541: power hardware code generator |
| 542: data test controller | |
| hardware code generator | |

What is claimed is:

1. A system for designing a power management cluster using a no-code approach, the system comprising:
a memory configured to store at least one instruction;
a power component storage in which power component information configuring a power management cluster is stored;
a hardware code logic storage in which hardware code logic for generating the designed power management cluster as hardware code is stored; and
at least one processor configured to execute the at least one instruction stored in the memory, wherein the at least one instruction comprises instructions for:
generating a power instance comprising a power management block, a power interface block, and a data controller block based on the power component information;
generating a data test controller instance comprising a test mode TDR block and a test control TDR block corresponding to the data controller block;
setting a connection between the data controller block and the data test controller instance; and
generating the hardware code based on the hardware code logic and connection information of the power instance and the data test controller instance.

2. The system for designing a power management cluster of claim 1, wherein the data controller block comprises:
a first test multiplexer block having a power control signal and preset data connected to input terminals and a pure test mode signal connected to a selection terminal; and
a second test multiplexer block having an output terminal of the first test multiplexer block and target test data of the test control TDR block connected to the input terminals and a target test mode signal of the test mode TDR block connected to the selection terminal.

3. The system for designing a power management cluster of claim 1, wherein the data test controller instance is implemented based on a built-in IEEE1687 standard.

4. The system for designing a power management cluster of claim 2, wherein:
the target test mode signal of the test mode TDR block activates or deactivates a test mode, and
the target test data of the test control TDR block is transmitted to the second test multiplexer block in the test mode.

5. The system for designing a power management cluster of claim 4, wherein the test control TDR block is configured with a number of flip-flop blocks corresponding to the number of bits of the target test data.

6. The system for designing a power management cluster of claim 1, wherein each of the test mode TDR block and the test control TDR block is configured via an internal joint test action group (IJTAG) interface.

7. The system for designing a power management cluster of claim 1, wherein the power component is at least one of a reset component, an isolation component, a switch control component, a retention component, an automatic power management component, a reference clock gating component, a memory component, a handshake component, a clock link component, a P-channel handshake component, a user-defined output component or a user-defined input component.

8. A method for designing a power management cluster using a no-code approach, the method being performed by at least one processor in a computer system comprising: a power component storage in which power component information configuring a power management cluster is stored; and a hardware code logic storage in which hardware code logic for generating the designed power management cluster as hardware code is stored, wherein the method comprises:
generating a power instance comprising a power management block, a power interface block, and a data controller block based on the power component information;
generating a data test controller instance comprising a test mode TDR block and a test control TDR block corresponding to the data controller block;
setting a connection between the data controller block and the data test controller instance; and
generating the hardware code based on the hardware code logic and connection information of the power instance and the data test controller instance.

9. The method for designing a power management cluster of claim 8, wherein the data controller block comprises:
a first test multiplexer block having a power control signal and preset data connected to input terminals and a pure test mode signal connected to a selection terminal; and
a second test multiplexer block having an output terminal of the first test multiplexer block and target test data of the test control TDR block connected to the input terminals and a target test mode signal of the test mode TDR block connected to the selection terminal.

10. The method for designing a power management cluster of claim 8, wherein the data test controller instance is implemented based on a built-in IEEE1687 standard.

11. The method for designing a power management cluster of claim 9, wherein:
the target test mode signal of the test mode TDR block activates or deactivates a test mode; and
the target test data of the test control TDR block is transmitted to the second test multiplexer block in the test mode.

12. The method for designing a power management cluster of claim 11, wherein the test control TDR block is configured with a number of flip-flop blocks corresponding to the number of bits of the target test data.

13. The method for designing a power management cluster of claim 8, wherein each of the test mode TDR block and the test control TDR block is configured via an internal joint test action group (IJTAG) interface.

14. The method for designing a power management cluster of claim 8, wherein the power component is at least one of a reset component, an isolation component, a switch control component, a retention component, an automatic power management component, a reference clock gating component, a memory component, a handshake component, a clock link component, a P-channel handshake component, a user-defined output component, or a user-defined input component.
